(19) United States
(12) Patent Application Publication
(10) Pub. No.: US 2011/0100462 A1
(43) Pub. Date: May 5, 2011

(54) Dye-sensitized solar cell and photoanode thereof

(75) Inventors: Wei-Cheng Tang, Taoyuan Hsien (TW); Ming-Si Wu, Taoyuan Hsien (TW); Kuan-Wei Lee, Taoyuan Hsien (TW); Hsin-Yi Chen, Taoyuan Hsien (TW)

(73) Assignee: Everlight USA, Inc., Pineville, NC (US)

(21) Appl. No.: 12/654,998

(22) Filed: Jan. 13, 2010

(30) Foreign Application Priority Data
Nov. 5, 2009 (TW) 098137543

(51) Int. Cl. H01L 51/46; H01L 51/48

(52) U.S. Cl. 136/261; 438/64; 257/40; 257/E21.499; 257/E51.027

(57) ABSTRACT

A dye-sensitized solar cell, a photoanode thereof, and a method for manufacturing the same are disclosed. The photoanode of the dye-sensitized solar cell of the present invention is prepared by a porous semiconductor layer absorbing two kinds of organic sensitized dyes, and one organic sensitized dye is represented by the following formula (I):

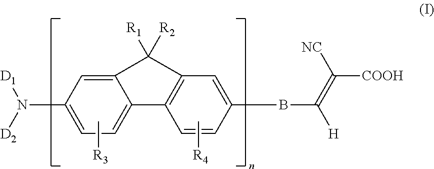

wherein, D₁, D₂, R₁, R₂, R₃, R₄, B, and n are defined the same as the specification.

These two kinds of the organic sensitized dyes have comparative absorption peaks, so the photoanode of the present invention can absorb solar spectrum with larger wavelength range. Hence, the dye-sensitized solar cell using the photoanode of the present invention has excellent photoelectric conversion efficiency.

### BACKGROUND OF THE INVENTION

1. Field of the Invention

The present invention relates to a novel photoanode for a dye-sensitized solar cell (DSC), which is prepared by a porous semiconductor layer sequentially absorbing various sensitized dyes and, more particularly, to a photoanode for a DSC, which is prepared by a porous semiconductor layer sequentially absorbing various organic sensitized dyes.

2. Description of Related Art

With the advance of industrial technology, the whole world is today facing two very serious problems, the energy crisis and the environmental pollution. One of the effective means to solve the global energy crisis and to reduce the environmental pollution is the solar cell, which can convert solar energy into electricity. Since the dye-sensitized solar cell has the advantages of low manufacturing cost, large-scale production, great flexibility, light transmittance, and being capable of incorporation in buildings, the application of the dye-sensitized solar cell has become more and more attractive.

Recently, Grätzel et al. disclosed a series of publications (for example, O'Regan, B.; Grätzel, M. Nature 1991, 353, 737), which show the practicability of the dye-sensitized solar cell. The general structure of the dye-sensitized solar cell comprises an anode, a cathode, a nano-sized titanium dioxide layer, a dye, and an electrolyte, wherein the dye plays a critical role in the conversion efficiency of the dye-sensitized solar cell. The dye suitable for the dye-sensitized solar cell must have characteristics in broad absorption spectrum, high molar absorption coefficient, thermal stability, and light stability.

The ruthenium complexes are the sensitized dyes with the highest conversion efficiency nowadays. However, the manufacturing cost of the ruthenium complexes is high, and there may be problems of short supply when the ruthenium complexes are used widely. The organic sensitized dyes have advantages of high molar absorption coefficient. Besides, it is possible to produce various organic sensitized dyes through molecular design. Hence, dye-sensitized solar cells with different colors can be manufactured by use of different organic sensitized dyes to improve the application flexibility of the dye-sensitized solar cells. In addition, it is also possible to change the color of the dye-sensitized solar cell to match with the color of objects. Currently, dye derivatives, such as Coumarin (Hara, K.; Sayama, K.; Arakawa, H.; Ohga, Y.; Shinpo, A.; Sug, S. Chem. Commun., 2001, 569), Indoline (Horiuchi, T.; Miura, H.; Sumioka, K.; Uchida, S. J. Am. Chem. Soc., 2004, 126 (39), 12218), and Merocyanine (Otaka, H.; Kira, M.; Yano, K.; Ito, S.; Mitekura, H.; Kawata, T.; Matsui, F. J. Photochem. Photobiol. A: Chem.; 2004, 164, 67), have already applied in the manufacture of dye-sensitized solar cells.

However, the wavelength rage that the organic sensitized dyes can absorb is narrow, so only little quantity of energy in the solar spectrum can be used. Hence, the photoelectric conversion efficiency of the dye-sensitized solar cell prepared with the organic sensitized dyes is limited and hard to be improved. Recently, Grätzel et al. published that the photoelectric conversion efficiency of the dye-sensitized solar cell can be improved through a co-absorption process with two kinds of organic dyes, compared with the dye-sensitized solar cell prepared with a single organic dyes(Kung D.; Walter P.; Nuesch F.; Kim S.; Ko J.; Comte P.; Zakeeruddin S. M.; Zakeeruddin M. K.; Grätzel, M. Langmuir 2007, 10906-10909). In addition, Toshiba Co. (Japan) also disclosed that the dye-sensitized solar cell prepared through a co-absorption process with an organic dye and an inorganic dye has improved photoelectric conversion efficiency (JP 2000-195569).

The co-absorption process with suitable sensitized dyes critically influences the photoelectric conversion efficiency of the dye-sensitized solar cell. Therefore, it is desirable to provide a combination of co-absorbed sensitized dyes, in order to improve the photoelectric conversion efficiency of the dye-sensitized solar cell.

### SUMMARY OF THE INVENTION

The object of the present invention is to provide a novel photoanode for a dye-sensitized solar cell, which is prepared with a porous semiconductor layer sequentially absorbing more than two kinds of sensitized dyes.

Another object of the present invention is to provide a novel photoanode for a dye-sensitized solar cell, which is prepared with a porous semiconductor layer sequentially absorbing more than two kinds of organic sensitized dyes.

Another object of the present invention is to provide a novel dye-sensitized solar cell, which is prepared with a porous semiconductor layer sequentially absorbing more than two kinds of sensitized dyes.

Further another object of the present invention is to provide a novel dye-sensitized solar cell, which is prepared with a porous semiconductor layer sequentially absorbing more than two kinds of organic sensitized dyes.

The maximum absorption wavelengths of dye compounds used in the dye-sensitized solar cell of the present invention are complementary to each other, so the dye compounds can absorb larger wavelength range of the solar spectrum. Therefore, the dye-sensitized solar cell of the present invention exhibits excellent photoelectric property.

The present invention also provides a method for manufacturing a dye-sensitized solar cell, and the manufactured dye-sensitized solar cell exhibits better photoelectric conversion efficiency.

The photoanode of the present invention comprises: a transparent substrate, a transparent conductive layer, a porous semiconductor layer, and dye compounds.

In the photoanode of the present invention, the material of the transparent substrate is not particularly limited, as long as the material of the substrate is a transparent material. Preferably, the material of the transparent substrate is a transparent material with good moisture resistance, solvent resistance and weather resistance. Thus, the dye-sensitized solar cell can resist moisture or gas from outside by the transparent substrate. The specific examples of the transparent substrate include, but are not limited to, transparent inorganic substrates, such as quartz and glass; transparent plastic substrates, such as poly(ethylene terephthalate) (PET), poly(ethylene 2,6-naphthalate) (PEN), polycarbonate (PC), polyethylene (PE), polypropylene (PP), and polyimide (PI). Additionally, the thickness of the transparent substrate is not particularly limited, and can be changed according to the transmittance and the demands for the properties of the dye-sensitized solar cell. Preferably, the material of the transparent substrate is glass. Furthermore, in the photoanode of the present invention, the material of the transparent conductive layer can be indium tin oxide (ITO), fluorine-doped tin oxide (FTO), ZnO—Ga₂O₃, ZnO—Al₂O₃, or tin-based oxides.

In addition, in the photoanode of the present invention, the porous semiconductive layer can be made of semiconductor particles. Suitable semiconductor particles may include: Si, TiO₂, SnO₂, ZnO, WO₃, Nb₂O₅, TiSrO₃, and the combination thereof. Preferably, the semiconductor particles are TiO₂ particles. The average diameter of the semiconductor particles may be 5 to 500 nm. Preferably, the average diameter of the semiconductor particles is 10 to 50 nm. Furthermore, the thickness of the porous semiconductive layer is 5-25 μm.

According to the photoanode of the present invention, the dyes comprise:

(a) a first organic sensitized dye represented by the following formula (I), or a salt thereof,

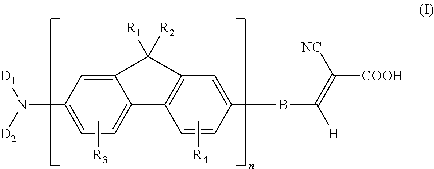

wherein
R₁, R₂, R₃, and R₄ are each independently H, C₁˜C₁₂ alkyl, C₁˜C₁₂ alkoxy, or halogen, and n is an integer of 1, 2, or 3;
D₁, and D₂ are each independently C₁˜C₁₂ alkyl,

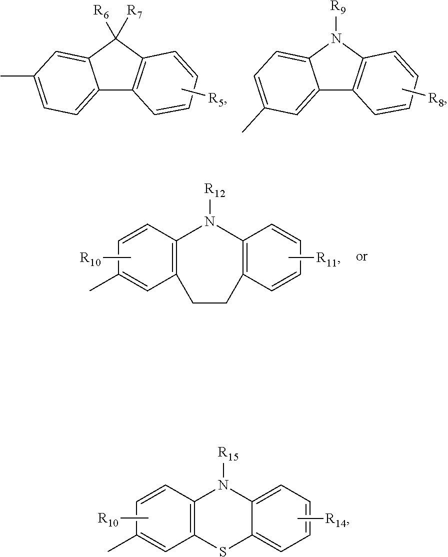

or D₁, D₂, and N bond together to form

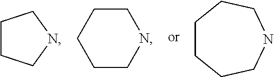

(i.e. C₄˜C₆ cycloheteroalkylene), wherein, R₅, R₆, R₇, R₈, R^{10,} R₁₁, R₁₃, and R₁₄ are each independently H, C₁˜C₁₂ alkyl, C₁˜C₁₂ alkoxy, amino, or halogen, R₉, R₁₂, and R₁₅ are each independently H, or C₁˜C₁₂ alkyl;

### B is

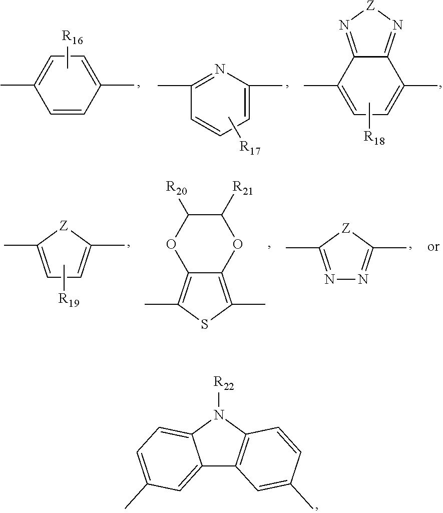

wherein R₁₆, R₁₇, and R₁₈ are each independently H, C₁˜C₁₂ alkyl, C₁˜C₁₂ alkoxy, or halogen, R₁₉, R₂₀, R₂₁, and R₂₂ are each independently H, or C₁˜C₁₂ alkyl, and Z is O, S, or Se; and

(b) a second organic sensitized dye, wherein the difference of the maximum absorption wavelength between the first organic sensitized dye and the second organic sensitized dye is larger than 50 nm.

In the above formula (I), R₁, R₂, R₃, and R₄ may be each independently H, C₁˜C₁₂ alkyl, C₁˜C₁₂ alkoxy, or halogen, and n may be 1, 2, or 3. Preferably, R₁, R₂, R₃, and R₄ are each independently H, C₁˜C₁₂ alkyl, C₁˜C₁₂ alkoxy, or halogen, and n is 1, or 2. More preferably, R₁, R₂, R₃, and R₄ are each independently H, C₁˜C₁₂ alkyl, or C₁˜C₁₂ alkoxy, and n is 1,or 2. Further more preferably, R₁, R₂, R₃, and R₄ are each independently H, C₁˜C₁₂ alkyl, or C₁˜C₁₂ alkoxy, and n is 1. Most preferably, R₁, R₂, R₃, and R₄ are each independently H, or C₁˜C₁₂ alkyl, and n is 1.

In the above formula (I), D₁, and D₂ may be each independently C₁˜C₁₂ alkyl,

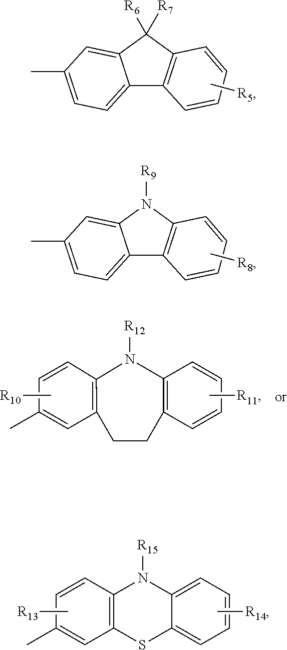

or D₁, D₂, and N bond together to form

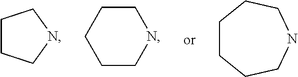

(i.e. C₄˜C₆ cycloheteroalkylene), wherein, R₅, R₆, R₇, R₈, R₁₀, R₁₁, R₁₃, and R₁₄ are each independently H, C₁˜C₁₂ alkyl, C₁˜C₁₂ alkoxy, amino, or halogen, R₉, R₁₂, and R₁₅ are each independently H, or C₁˜C₁₂ alkyl. Preferably, D₁, and D₂ are each independently C₁˜C₁₂ alkyl,

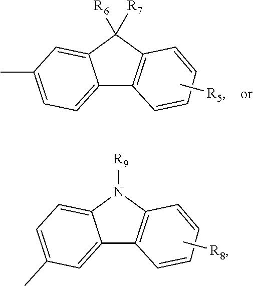

wherein, R₅, R₆, R₇, and R₈ are each independently H, C₁˜C₁₂ alkyl, C₁˜C₁₂ alkoxy, amino, or halogen, and R₉ is H, or C₁˜C₁₂ alkyl. More preferably, D₁, and D₂ are each independently C₁˜C₁₂ alkyl,

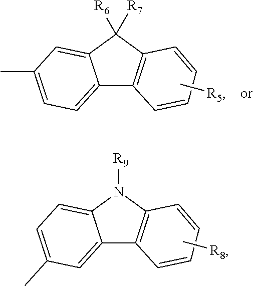

wherein, R₅, R₆, R₇, and R₈ are each independently H, C₁˜C₁₂ alkyl, or C₁˜C₁₂ alkoxy, and R₉ is H, or C₁˜C₁₂ alkyl. Most preferably, D₁, and D₂ are each independently C₁˜C₁₂ alkyl,

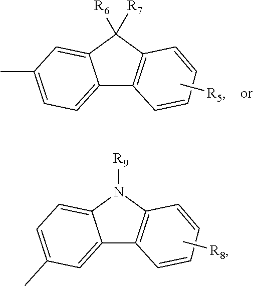

wherein, R₅, R₆, R₇, R₈, and R₉ are each independently H, or C₁˜C₁₂ alkyl.

In addition, according to one aspect of the present invention, in the above formula (I), D₁, and D₂ may be each independently C₁˜C₁₂ alkyl, or

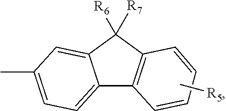

wherein, R₅, R₆, and R₇ are each independently H, C₁˜C₁₂ alkyl, C₁˜C₁₂ alkoxy, amino, or halogen. Preferably, R₅, R₆, and R₇ in D₁, and D₂ are each independently H, C₁˜C₁₂ alkyl, or C₁˜C₁₂ alkoxy. More preferably, R₅, R₆, and R₇ in D₁, and D₂ are each independently H, or C₁˜C₁₂ alkyl. Most preferably, R₅ in D₁, and D₂ is H, and R₆, and R₇ are each independently C₁˜C₁₂ alkyl. Most preferably, R₅ in D₁, and D₂ is H, and R₆, and R₇ are each independently C₁˜C₁₂ alkyl.

In the above formula (I), B may be

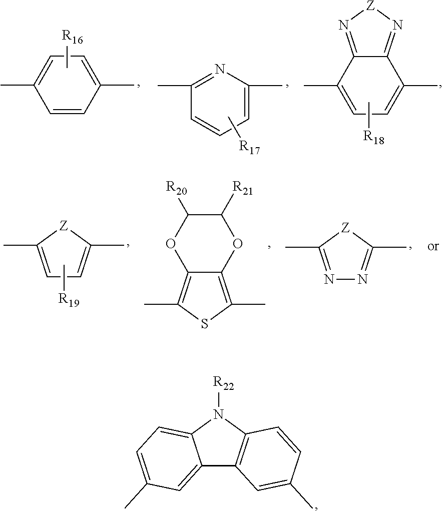

wherein R₁₆, R₁₇, and R₁₈ are each independently H, C₁˜C₁₂ alkyl, C₁˜C₁₂ alkoxy, or halogen, R₁₉, R₂₀, R₂₁, and R₂₂ are each independently H, or C₁˜C₁₂ alkyl, and Z is O, S, or Se. Preferably, B is

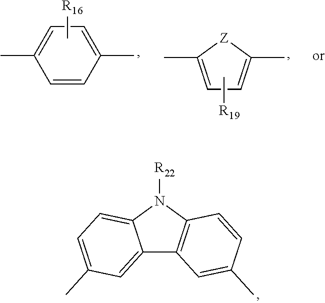

wherein R₁₆, is H, C₁˜C₁₂ alkyl, C₁˜C₁₂ alkoxy, or halogen, R₁₉, and R₂₂ are each independently H, or C₁˜C₁₂ alkyl, and Z is O, S, or Se. More preferably, B is

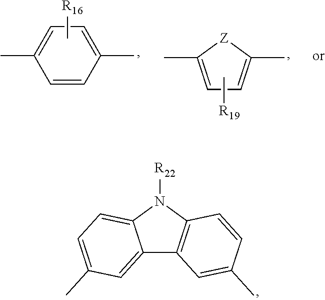

wherein R₁₆, is H, C₁˜C₁₂ alkyl, C₁˜C₁₂ alkoxy, or halogen, R₁₉, and R₂₂ are each independently H, or C₁˜C₁₂ alkyl, and Z is S. Most preferably, B is

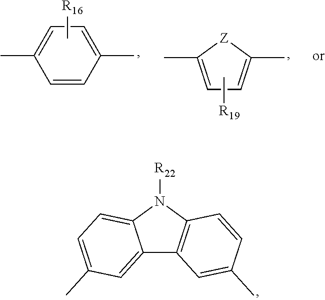

wherein R₁₆, R₁₉, and R₂₂ are each independently H, or C₁˜C₁₂ alkyl, and Z is S.

In addition, according to another aspect of the present invention, in the above formula (I), B may be

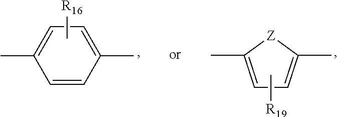

wherein R₁₆ is H, C₁˜C₁₂ alkyl, C₁˜C₁₂ alkoxy, or halogen, R₁₉ is H, or C₁˜C₁₂ alkyl, and Z is O, S, or Se. Preferably, B is

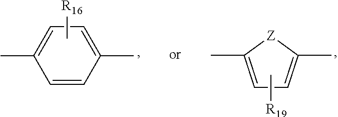

wherein R₁₆ is H, C₁˜C₁₂ alkyl, C₁˜C₁₂ alkoxy, or halogen, R₁₉ is H, or C₁˜C₁₂ alkyl, and Z is S. More preferably, B is

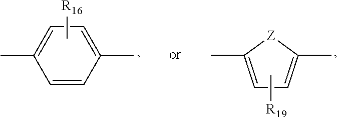

wherein R₁₆ is H, C₁˜C₁₂ alkyl, or C₁˜C₁₂ alkoxy, R₁₉ is H, or C₁˜C₁₂ alkyl, and Z is S. Further more preferably, B is

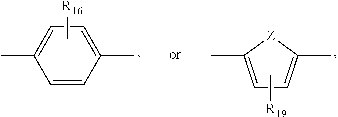

wherein R₁₆, and R₁₉ are each independently H, or C₁˜C₁₂ alkyl, and Z is S. Most preferably, B is

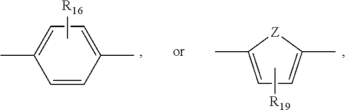

wherein R₁₆, and R₁₉ are H, and Z is S.

The specific examples of the first organic sensitized dye represented by the above formula (I) are:

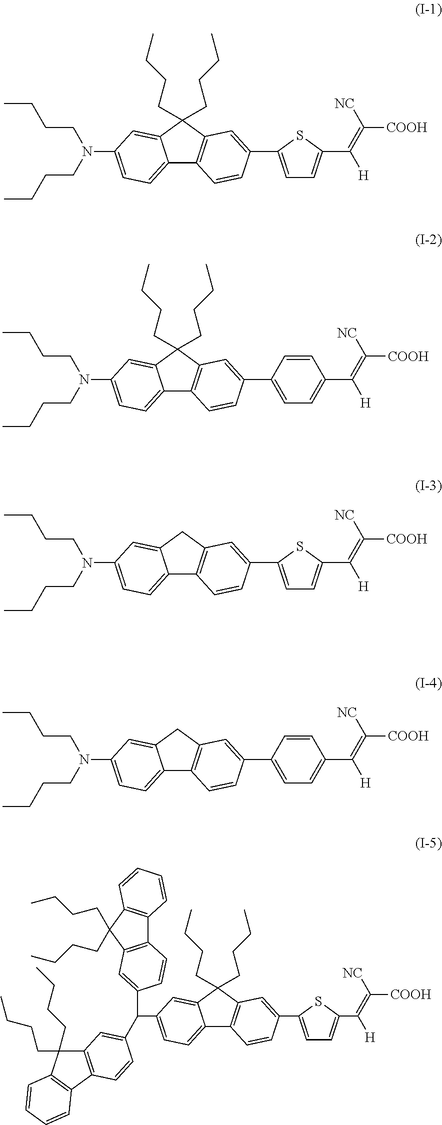

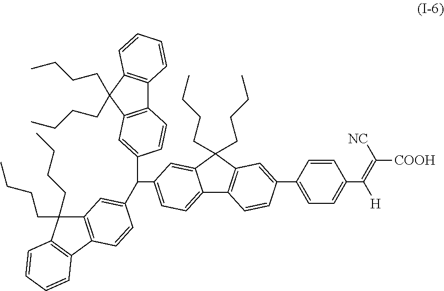

The specific examples of the second organic sensitized dye in the component (b) are:

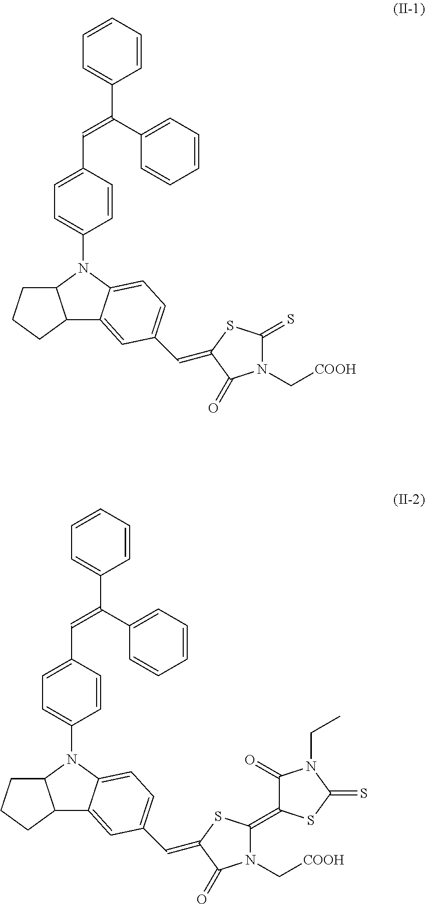

In the present invention, the molecules of the sensitized dyes are presented in form of free acid. However, the actual forms of the sensitized dyes may be salts, and more likely, may be alkaline metal salts or quaternary ammonium salts.

The dye-sensitized solar cell of the present invention comprises: a photoanode; a cathode; and an electrolyte layer, disposed between the photoanode and the cathode.

According to the dye-sensitized solar cell of the present invention, the photoanode is the aforementioned photoanode.

In addition, the material of the cathode for the dye-sensitized solar cell is not particularly limited, and may include any material with conductivity. Otherwise, the material of the cathode can be an insulating material, as long as there is a conductive layer formed on the surface of the cathode facing the photoanode. Any material with electrochemical stability can be used as the material of the cathode. The unlimited examples suitable for the material of the cathode include: Pt, Au, C, or the like.

Furthermore, the material used in the electrolyte layer of the dye-sensitized solar cell is not particularly limited, and can be any material, which can transfer electrons and/or holes.

On the other hand, the present invention also provides a method for manufacturing the dye-sensitized solar cell, which comprises the following steps: (1) providing the aforementioned photoanode; (2) providing a second substrate; (3) forming a metal layer on the second substrate; (4) composing the photoanode and the second substrate, wherein the semiconductor layer faces to the metal layer, and a containing space is formed between the photoanode and the second substrate; (5) filling the containing space with a electrolyte; and (6) sealing the containing space.

### DETAILED DESCRIPTION OF THE PREFERRED EMBODIMENT

The organic sensitized dye represented by the formula (I) of the present invention may be synthesized according to the following scheme 1.

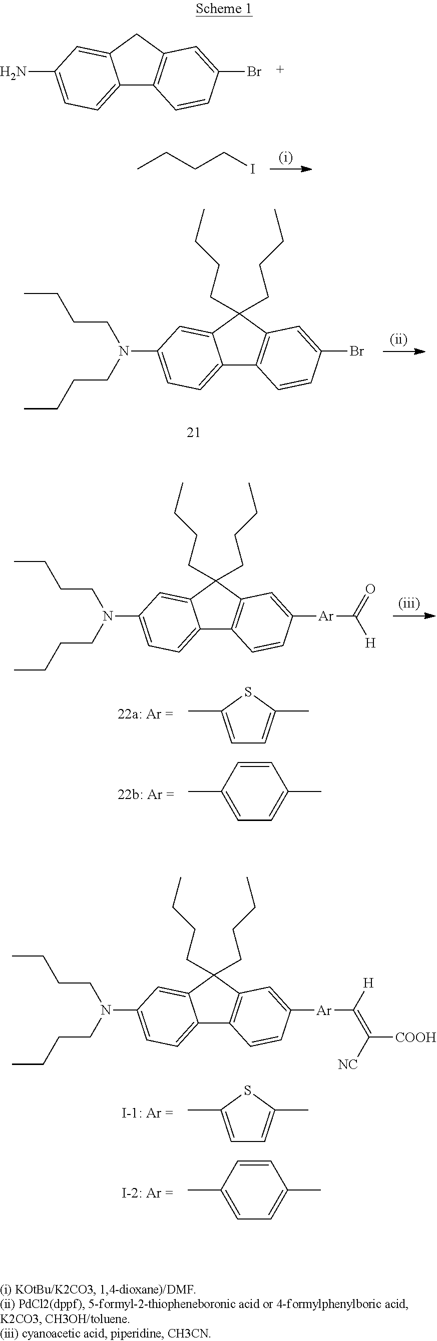

As shown in Scheme 1, 7-bromo-9H-fluoren-2-ylamine is reacted with 1-iodobutane to form (7-bromo-9,9-dibutyl-9H-fluoren-2-yl)-dibutylamine (21). Then, the Suzuki coupling reaction is performed by reacting (7-bromo-9,9-dibutyl-9H-fluoren-2-yl)-dibutyl-amine (21) with 5-formyl-2-thiopheneboronic acid to obtain 5-(9,9-Dibutyl-7-dibutyl amino-9H-fluoren-2-yl)-thiophene-2-carbaldehyde (22a). Finally, in acetonitrile, 5-(9,9-Dibutyl-7-dibutylamino-9H-fluoren-2-yl)-thiophene-2-carbaldehyde (22a) is reacted with cyanoacetic acid by using piperidine as a catalyst, to obtain 2-cyano-3-[5-(9,9-dibutyl-7-dibutylamino-9H-fluoren-2-yl)-thiophen-2-yl]acrylic acid (I-1).

The organic sensitized dyes represented by the formulas (II-1) and (II-2) are commercial available.

The method for manufacturing the dye-sensitized solar cell of the present invention is not particularly limited, and the dye-sensitized solar cell of the present invention can be manufacture by the conventional methods known in the art.

The material of the transparent substrate is not particularly limited, as long as the material of the substrate is a transparent material. Preferably, the material of the transparent substrate is a transparent material with good moisture resistance, solvent resistance and weather resistance. Thus, the dye-sensitized solar cell can resist moisture or gas from outside by the transparent substrate. The specific examples of the transparent substrate include, but are not limited to, transparent inorganic substrates, such as quartz and glass; transparent plastic substrates, such as poly(ethylene terephthalate) (PET), poly(ethylene 2,6-naphthalate) (PEN), polycarbonate (PC), polyethylene (PE), polypropylene (PP), and polyimide (PI). Additionally, the thickness of the transparent substrate is not particularly limited, and can be changed according to the transmittance and the demands for the properties of the dye-sensitized solar cell. In a specific embodiment, the material of the transparent substrate is a glass substrate.

Furthermore, the material of the transparent conductive layer can be indium tin oxide (ITO), fluorine-doped tin oxide (FTO), ZnO-Ga₂O₃, ZnO-Al₂O₃, or tin-based oxides. In a specific embodiment, fluorine-doped tin oxide is used for the transparent conductive layer.

In addition, the porous semiconductive layer is made of semiconductor particles. Suitable semiconductor particles may include Si, TiO₂, SnO₂, ZnO, WO₃, Nb₂O₅, TiSrO₃, and the combination thereof. First, the semiconductor particles are prepared in a form of paste, and then the transparent conductive substrate is coated with the paste. The coating process used herein can be blade coating, screen printing, spin coating, spray coating, or wetting coating. Additionally, the coating can be held for one time or many times, in order to obtain a porous semiconductive layer with suitable thickness. The semiconductive layer can be a single layer or multiple layers, wherein each layer of the multiple layers is formed by semiconductor particles with different diameters. For example, the semiconductor particles with diameters of 5 to 50 nm is coated in a thickness of 5 to 20 μm, and then the semiconductor particles with diameters of 200 to 400 nm are coated in a thickness of 3 to 5 μm thereon. After drying the coated substrate at 50-100° C., the coated substrate is sintered at 400-500° C. for 30 min to obtain a multilayer semiconductive layer.

The organic sensitized dyes can be dissolved in a suitable solvent to prepare a dye solution. Suitable solvents include, but are not limited to, acetonitrile, methanol, ethanol, propanol, butanol, dimethyl formamide, N-methyl-2-pyrrolidinone, or the combination thereof. Herein, the transparent substrate coated with the semiconductive layer is soaked into a dye solution to make the semiconductive layer absorb the dye in the dye solution completely. After the dye absorption is completed, the transparent substrate coated with the semiconductive layer is taken out and dried to obtain a photoanode for a dye-sensitized solar cell.

Besides, the material of the cathode for the dye-sensitized solar cell is not particularly limited, and may include any material with conductivity. Otherwise, the material of the cathode can be an insulating material, as long as there is a conductive layer formed on the surface of the cathode facing the photoanode. The material of the cathode can be a material with electrochemical stability. The unlimited examples suitable for the material of the cathode include: Pt, Au, C, or the like.

Furthermore, the material used in the electrolyte layer of the dye-sensitized solar cell is not particularly limited, and can be any material, which can transfer electrons and/or holes. In addition, the liquid electrolyte can be a solution of acetonitrile containing iodine, a solution of N-methyl-2-pyrrolidinone containing iodine, or a solution of 3-methoxy propionitrile containing iodine. In a specific embodiment, the liquid electrolyte can be a solution of acetonitrile containing iodine.

One specific method for manufacturing the dye-sensitized solar cell of the present invention is presented as follows.

First, a glass substrate covered with fluorine-doped tin oxide (FTO) is coated with a paste containing TiO₂ particles with diameter of 20-30 nm for one time or several times by a screen printing process. Then, the coated glass substrate is sintered at 450° C. for 30 min.

The organic sensitized dye is dissolved in a mixture of acetonitrile and t-butanol (1:1 v/v) to formulate a dye solution. Then, the aforementioned glass substrate with porous TiO₂ layer is soaked into the dye solution. After the porous TiO₂ layer absorbs the organic sensitized dye in the dye solution, the resulting glass substrate is taken out and dried to obtain a photoanode.

A glass substrate covered with fluorine-doped tin oxide is drilled to form an inlet with a diameter of 0.75 μm, wherein the inlet is used for injecting the electrolyte. Then, a solution of H₂PtCl₆ is coated on the glass substrate covered with fluorine-doped tin oxide, and the glass substrate is heated to 400° C. for 15 min to obtain a cathode.

Sequentially, a thermoplastic polymer layer with a thickness of 60 um is disposed between the photoanode and the cathode. These two electrodes are pressed at 120 to 140° C. to adhere with each other.

Then, an electrolyte is injected, wherein the electrolyte is a solution of acetonitrile containing 0.03 M I₂/0.3 M LiI/0.5 M t-butyl-pyridine. After the inlet is sealed with thermoplastic polymer layer, a dye-sensitized solar cell of the present invention is obtained.

The following examples are intended for the purpose of illustration of the present invention. However, the scope of the present invention should be defined as the claims appended hereto, and the following examples should not be construed as in any way limiting the scope of the present invention. In the following examples, the compounds are represented in forms of free acids, but the actual forms of the sensitized dyes may be salts, and more likely, may be alkaline metal salts or quaternary ammonium salts. In addition, without specific explanations, the unit of the parts and percentages used in the examples is calculated by weight, and the temperature is represented by Celsius degrees (° C.). The relation between the parts by weight and the parts by volume is just like the relation between kilogram and liter.

Hereafter, the method for synthesizing organic sensitized dyes and the method for manufacturing a dye-sensitized solar cell are detail described, and the method for synthesizing the organic sensitized dyes can be referred to the aforementioned scheme 1.

### EXAMPLE 1

Synthesis of (7-Bromo-9,9-Dibutyl-9H-Fluoren-2-yl)-Dibutylamine (21)

Under N₂ atmosphere, 0.52 parts of 7-bromo-9H-fluoren-2-ylamine, 2.21 parts of 1-iodobutane, 0.67 parts of potassium tert-butoxide, and 0.83 parts of potassium carbonate were added into 10 parts of dry dimethylformamide and 10 parts of 1,4-dioxane, followed by stirring and mixing. Then, the reaction mixture was heated to 95° C. and reacted for 24 hours. After the reaction mixture was cooled, the reaction was quenched with water, the product was extracted with diethyl ether, and a dehydration process was performed with magnesium sulfate. After removing the solvent, the residual was purified in a silica gel column by using dichloromethane/hexane as an eluent, to obtain a compound (21) of the present example. This compound was in a form of a light yellow solid, and the yield of this compound was 83%.

### EXAMPLE 2

Synthesis of 5-(9,9-Dibutyl-7-Dibutylamino-9H-Fluoren-2-yl)-Thiophene-2-Carbaldehyde (22a)

Under N₂ atmosphere, 0.49 parts of (7-bromo-9,9-dibutyl-9H-fluoren-2-yl)-dibutylamine (21), 0.19 parts of 5-formyl-2-thiopheneboronic acid, 0.41 parts of potassium carbonate, and 0.16 parts of PdCl₂(dppf) were added into 5 parts of toluene and 5 parts of CH₃OH, followed by stirring and mixing. Then, the reaction mixture was heated to 60° C. and reacted for 18 hours. The reaction was quenched with water, the product was extracted with diethyl ether, and a dehydration process was performed with magnesium sulfate. After removing the solvent, the residual was purified in a silica gel column by using dichloromethane/hexane as an eluent, to obtain a compound (22a) of the present example. This compound was in a form of a tangerine solid, and the yield of this compound was 52%.

### EXAMPLE 3

Synthesis of 4-(9,9-Dibutyl-7-Dibutylamino-9H-Fluoren-2-yl)-Benzaldehyde (22b)

The process for preparing the compound of the present example is the same as that described in Example 2, except that 5-formyl-2-thiopheneboronic acid is substituted with 0.18 parts of 4-formylphenylboronic acid, to obtain a -compound (22b) of the present example. This compound was in a form of yellow solid, and the yield of this compound was 61%.

### EXAMPLE 4

Synthesis of 2-Cyano-3-[5-(9,9-Dibutyl-7-Dibutylamino-9H-Fluoren-2-yl)-Thiophen-2-yl]-Acrylic Acid (I-1)

Under N₂ atmosphere, 0.23 parts of 5-(9,9-dibutyl-7-dibutylamino-9H-fluoren-2-yl)-thiophene-2-carbaldehyde (22a), 0.05 parts of cyanoacetic acid, and 0.017 parts of piperidine were added into 10 parts of acetonitrile, followed by stirring and mixing. Then, the reaction mixture was heated to 90° C. and reacted for 6 hours. After the reaction mixture was cooled to room temperature, the reaction mixture was filtrated to obtain a solid. Then, the solid was sequentially washed with water, ether, and acetonitrile to obtain a dark red solid. Finally, this dark red solid was purified in a silica gel column by using dichloromethane/methanol as an eluent, to obtain a compound (I-1) of the present example. This compound was in a form of a dark red solid, and the yield of this compound was 86%.

### EXAMPLE 5

Synthesis of 2-Cyano-3-[4-(9,9-dibutyl-7-dibutylamino-9H-fluoren-2-yl)-phenyl]-acrylic acid (I-2)

The process for preparing the compound of the present example is the same as that described in Example 4, except that 5 -(9,9-dibutyl-7-dibutylamino-9H-fluoren-2-yl)-thiophene-2-carbaldehyde (22a) is substituted with 4-(9,9-dibutyl-7-dibutylamino-9H-fluoren-2-yl)-benzaldehyde (22b) in the present example. This compound was in a form of tangerine solid, and the yield of this compound was 68%.

### COMPARATIVE EXAMPLES 1-40

### Preparation of a Dye-Sensitized Solar Cell

A glass substrate covered with fluorine-doped tin oxide (FTO) was coated with a paste containing TiO₂ particles with diameter of 20-30 nm for one time or several times, wherein the thickness of the glass substrate was 4 mm and the electric resistance of the glass substrate is 10 Ω. Then, the coated glass substrate was sintered at 450° C. for 30 min, and the thickness of the sintered porous TiO₂ layer was 10 to 12 μm.

The second organic sensitized dyes of formulas (II-1) and (II-2) were formulated in a concentration of 1×10⁻⁴ M, and the first organic sensitized dyes of formulas (I-1) and (I-2) were formulated in a concentration 5×10⁻⁴ M of , respectively. Then, the anodes coated with TiO₂ layer were soaked into the dye solutions of formula (I-1), (I-2), (II-1), and (II-2) for 2, 5, 7, and 24, respectively. The soaking conditions are listed in the following Table 1.

A glass substrate covered with fluorine-doped tin oxide was drilled to form an inlet with a diameter of 0.75 μm, wherein the inlet was used for injecting the electrolyte. Then, a solution of H₂PtCl₆ (2 mg Pt in 1 ml ethanol) was coated on the glass substrate covered with fluorine-doped tin oxide, and the resulting glass substrate was heated to 400° C. for 15 min to obtain a cathode.

Sequentially, a thermoplastic polymer layer with a thickness of 60 was disposed between the photoanode and the cathode. These two electrodes were pressed at 120 to 140° C. to adhere with each other. Then, an electrolyte was injected, which was a solution of acetonitrile containing 0.03 M I₂/0.3 M LiI/0.5 M t-butyl-pyridine. After the inlet was sealed with thermoplastic polymer layer, a dye-sensitized solar cell of the present comparative example was obtained.

TABLE 1

| | Soaking time | Organic sensitized dye |
|---|---|---|
| Comparative example 1 | 2 H | I-2 |
| Comparative example 2 | 5 H | I-2 |
| Comparative example 3 | 8 H | I-2 |
| Comparative example 4 | 24 H | I-2 |
| Comparative example 5 | 8 H | I-1 |
| Comparative example 6 | 2 H | II-2 |
| Comparative example 7 | 5 H | II-2 |
| Comparative example 8 | 8 H | II-2 |
| Comparative example 9 | 24 H | II-2 |
| Comparative example 10 | 8 H | II-1 |

### EXAMPLES 6-12

### Preparation of a Dye-Sensitized Solar Cell

A glass substrate covered with fluorine-doped tin oxide (FTO) was coated with a paste containing TiO₂ particles with diameter of 20˜30 nm for one time or several times, wherein the thickness of the glass substrate was 4 mm and the electric resistance of the glass substrate is 10 Ω. Then, the coated glass substrate was sintered at 450° C. for 30 min, and the thickness of the sintered porous TiO₂ layer was 10 to 12 μm.

Sequentially, a co-absorption process was performed with two kinds of organic sensitized dyes. First, the second organic sensitized dyes of formulas (II-1) and (II-2) were formulated in a concentration of 1×10⁻⁴ M, and the first organic sensitized dyes of formulas (I-1) and (I-2) were formulated in a concentration 5×10⁻⁴ M of , respectively. The anodes coated with TiO₂ layer were soaked into the dye solution of the second organic sensitized dye for 4 hours, and then soaked into the dye solution of the first organic sensitized dye for 1, 2, 4, and 6 hours. The soaking conditions are listed in the following Table 2.

A glass substrate covered with fluorine-doped tin oxide was drilled to form an inlet with a diameter of 0.75 μm wherein the inlet was used for injecting the electrolyte. Then, a solution of H₂PtCl₆ (2 mg Pt in 1 ml ethanol) was coated on the glass substrate covered with fluorine-doped tin oxide, and the resulting glass substrate was heated to 400° C. for 15 min to obtain a cathode.

Sequentially, a thermoplastic polymer layer with a thickness of 60 μm was disposed between the photoanode and the cathode. These two electrodes were pressed at 120 to 140° C. to adhere with each other.

Then, an electrolyte was injected, which was a solution of acetonitrile containing 0.03 M I₂/0.3 M LiI/0.5 M t-butyl-pyridine. After the inlet was sealed with thermoplastic polymer layer, a dye-sensitized solar cell of the present example was obtained.

TABLE 2

| | Soaking | Second organic | Soaking | First organic |
|---|---|---|---|---|
| | time | sensitized dye | time | sensitized dye |
| Example 6 | 4 H | II-2 | 1 H | I-2 |
| Example 7 | 4 H | II-2 | 2 H | I-2 |
| Example 8 | 4 H | II-2 | 4 H | I-2 |
| Example 9 | 4 H | II-2 | 6 H | I-2 |
| Example 10 | 4 H | II-2 | 4 H | I-1 |
| Example 11 | 4 H | II-1 | 4 H | I-1 |
| Example 12 | 4 H | II-1 | 4 H | I-2 |

### Testing Methods and Results

### UV-Vis Spectrum

The organic sensitized dyes of formulas (I-1), (I-2), (II-1), and (II-2) were formulated with methylene chloride as a solvent, to obtain dye solutions. Then, the UV-Vis spectrum of each dye solution was measured.

The λₘₐₓ of the organic sensitized dye of formula (I-1) is 427 nm, the λₘₐₓ of the organic sensitized dye of formula (I-2) is 380 nm, the λₘₐₓ of the organic sensitized dye of formula (II-1) is 491 nm, and the λₘₐₓ of the organic sensitized dye of formula (II-2) is 526 nm.

### Test for the Photoelectric Characteristics

The short circuit current (J_{SC}), open circuit voltage (V_{OC}), filling factor (FF), and photoelectric conversion efficiency (η) of the dye-sensitized solar cells prepared by Comparative examples 1-4, and 6-9, and Examples 6-9 were measured under the illumination of AM 1.5 stimulated light. The testing results are shown in the following Tables 3 and 4.

TABLE 3
Testing results of the dye-sensitized solar cells

| | J_{SC} | V_{OC} | | |
|---|---|---|---|---|
| | (mA/cm²) | (V) | FF | η (%) |
| Comparative example 1 | 7.51 | 0.69 | 0.62 | 3.23 |
| Comparative example 2 | 7.54 | 0.68 | 0.61 | 3.11 |
| Comparative example 3 | 5.46 | 0.63 | 0.64 | 2.20 |
| Comparative example 4 | 5.64 | 0.67 | 0.61 | 2.24 |
| Comparative example 6 | 11.10 | 0.67 | 0.55 | 4.09 |
| Comparative example 7 | 11.33 | 0.66 | 0.57 | 4.30 |
| Comparative example 8 | 10.61 | 0.65 | 0.53 | 3.67 |
| Comparative example 9 | 9.93 | 0.65 | 0.56 | 3.67 |
| Example 6 | 11.70 | 0.70 | 0.58 | 4.80 |
| Example 7 | 11.96 | 0.69 | 0.59 | 4.86 |
| Example 8 | 11.93 | 0.70 | 0.59 | 5.00 |
| Example 9 | 12.81 | 0.70 | 0.61 | 5.56 |

According to the test results shown in Table 3, the photoelectric characteristics of the dye-sensitized solar cells (Examples 6-9), which are prepared with both the first organic sensitized dye (a) and the second organic sensitized dye (b) through a co-absorption process, are better than those prepared with a single first organic sensitized dye (a) (i.e. Comparative examples 1-4) or with a single second organic sensitized dye (b) (i.e. Comparative examples 6-9).

TABLE 4
Testing results of the dye-sensitized solar cells

| | J_{SC} | V_{OC} | | |
|---|---|---|---|---|
| | (mA/cm²) | (V) | FF | η (%) |
| Comparative example 3 | 5.46 | 0.63 | 0.64 | 2.20 |
| Comparative example 5 | 8.15 | 0.68 | 0.64 | 3.55 |
| Comparative example 8 | 10.61 | 0.65 | 0.53 | 3.67 |
| Comparative example 10 | 6.76 | 0.64 | 0.60 | 2.65 |
| Example 8 | 11.93 | 0.70 | 0.59 | 5.00 |
| Example 10 | 10.62 | 0.69 | 0.65 | 4.75 |
| Example 11 | 9.34 | 0.66 | 0.62 | 3.81 |
| Example 12 | 9.85 | 0.73 | 0.66 | 4.80 |

According to the test results shown in Table 4, the photoelectric characteristics of the dye-sensitized solar cells (Examples 8, 10, and 11), which are prepared with both the first organic sensitized dye (formula (I-1) and (I-2)) and the second organic sensitized dye (formula (II-1) and (II-2)) through a co-absorption process, are better than those prepared with a single first organic sensitized dye (a) (i.e. Comparative examples 3-5) or with a single second organic sensitized dye (b) (i.e. Comparative examples 8-10).

In other words, the structure of the first organic sensitized dye is different from that of the second organic sensitized dye, so that the maximum absorption wavelength between the first organic sensitized dye and the second organic sensitized dye is different in the UV-vis spectrum. Hence, when two organic sensitized dyes with different absorption wavelengths are co-absorbed to prepare the dye-sensitized solar cell, it is possible to increase the spectrum utilization in visible region. In addition, the method for performing the co-absorption process can be adjusted according to the types of the organic sensitized dyes, to increase the photoelectric efficiency of the solar cell.

In conclusion, the present invention is different from the prior arts in several ways, such as in purposes, methods and efficiency, or even in technology and research and design. Although the present invention has been explained in relation to its preferred embodiment, it is to be understood that many other possible modifications and variations can be made without departing from the scope of the invention as hereinafter claimed. Hence, the scope of the present invention should be defined as the claims appended hereto, and the foregoing examples should not be construed as in any way limiting the scope of the present invention.

What is claimed is:

1. A photoanode, which is a substrate with a semiconductor layer absorbing dyes, wherein the dyes comprise:
(a) a first organic sensitized dye represented by the following formula (I), or a salt thereof, 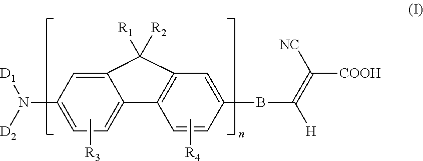
wherein
R₁, R₂, R₃, and R₄ are each independently H, C₁˜C₁₂ alkyl, C₁˜C₁₂ alkoxy, or halogen, and n is an integer of 1, 2, or 3;
D₁, and D₂ are each independently C₁˜C₁₂ alkyl, 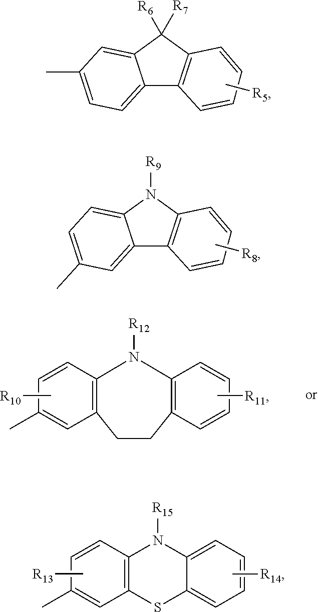
or D₁, D₂, and N bond together to form 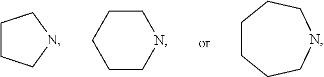
wherein, R₅, R₆, R₇, R₈, R₁₀, R₁₁, R₁₃, and R₁₄ are each independently H, C₁˜C₁₂ alkyl, C₁˜C₁₂ alkoxy, amino, or halogen, R₉, R₁₂, and R₁₅ are each independently H, or C₁˜C₁₂ alkyl;
B is 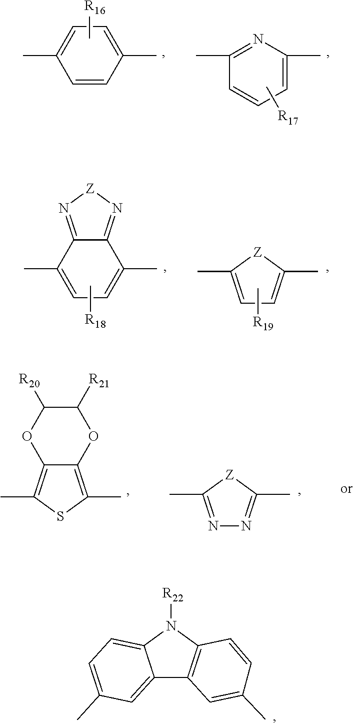
wherein R₁₆, R₁₇, and R₁₈ are each independently H, C₁˜C₁₂ alkyl, C₁˜C₁₂ alkoxy, or halogen, R₁₉, R₂₀, R₂₁, and R₂₂ are each independently H, or C₁˜C₁₂ alkyl, and Z is O, S, or Se; and
(b) a second organic sensitized dye, wherein the difference of the maximum absorption wavelength between the first organic sensitized dye and the second organic sensitized dye is larger than 50 nm.

2. The photoanode as claimed in claim 1, wherein n is 1.

3. The photoanode as claimed in claim 1, wherein D₁, and D₂ are each independently C ₁˜C₁₂ alkyl, 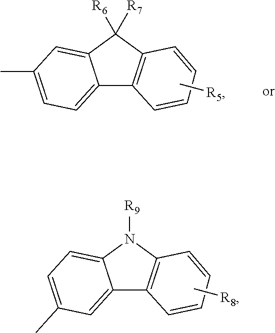
wherein, R₅, R₆, R₇, and R₈ are each independently H, C₁˜C₁₂ alkyl, C₁˜C₁₂ alkoxy, amino, or halogen, R₉ is H, or C₁˜C₁₂ alkyl.

4. The photoanode as claimed in claim 3, wherein B is 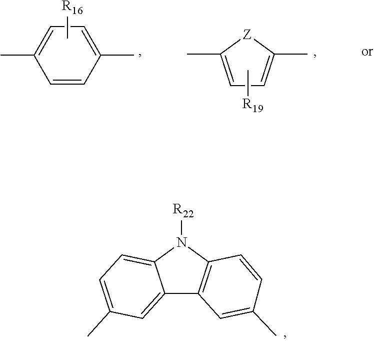
wherein R₁₆ is H, C₁˜C₁₂ alkyl, C₁˜C₁₂ alkoxy, or halogen, R₁₉, and R₂₂ are each independently H, or C₁˜C₁₂ alkyl, and Z is O, S, or Se.

5. The photoanode as claimed in claim 4, wherein Z is S, and n is 1.

6. The photoanode as claimed in claim 5, wherein R₁, R₂, R₃, R₄, R₅, R₆, R₇, R₈, and R₁₆ are each independently H, C₁˜C₁₂ alkyl, or C₁˜C₁₂ alkoxy.

7. The photoanode as claimed in claim 6, wherein R₁, _{R2,} R₃, R₄, R₅, R₆, R₇, R₈, and R₁₆ are each independently H, or C₁˜C₁₂ alkyl.

8. The photoanode as claimed in claim 1, wherein B is 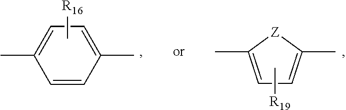
wherein R₁₆ is H, C₁˜C₁₂ alkyl, C₁˜C₁₂ alkoxy, or halogen, R₁₉ is H, or C₁˜C₁₂ alkyl, and Z is O, S, or Se.

9. The photoanode as claimed in claim 8, wherein D₁, and D₂ are each independently C₁˜C₁₂ alkyl, or 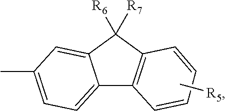
wherein, R₅, R₆, and R₇ are each independently H, C₁˜C₁₂ alkyl, C₁˜C₁₂ alkoxy, amino, or halogen.

10. The photoanode as claimed in claim 9, wherein Z is S, and n is 1.

11. The photoanode as claimed in claim 10, wherein R₁, _{R2,} R₃, R₄, R₅, R₆, R₇, and R₁₆ are each independently H, C₁˜C₁₂ alkyl, or C₁˜C₁₂ alkoxy.

12. The photoanode as claimed in claim 11, wherein R₁, R₂, R₃, R₄, R₅, R₆, R₇, and R₁₆ are each independently H, or C₁˜C₁₂ alkyl.

13. The photoanode as claimed in claim 12, wherein, R₁₆, and R₁₉ is H.

14. The photoanode as claimed in claim 1, wherein the first organic sensitized dye in the component (a) is a compound represented by the following formula (I-1), or (I-2), or a salt thereof:

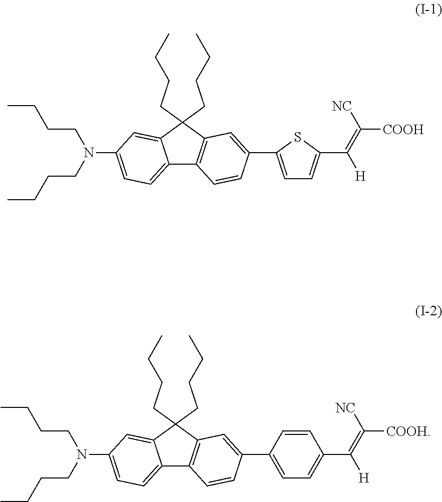

15. The photoanode as claimed in claim 1, wherein the second organic sensitized dye in the component (b) is a compound represented by the following formula (II-1), or (II-2), or a salt thereof:

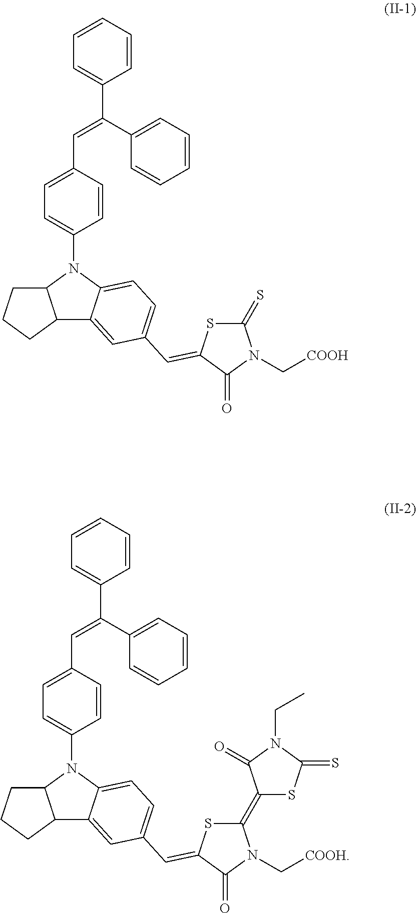

16. The photoanode as claimed in claim 14, wherein the second organic sensitized dye in the component (b) is a compound represented by the formula (II-1), or (II-2), or a salt thereof.

17. A dye-sensitized solar cell, comprising:
(A) a photoanode, which is a substrate with a semiconductor layer absorbing dyes, wherein the dyes comprise: (a) a first organic sensitized dye represented by the following formula (I), or a salt thereof, 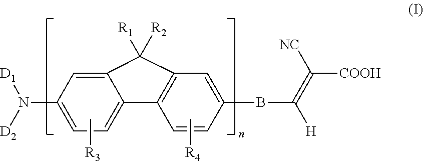
wherein
R₁, R₂, R₃, and R₄ are each independently H, C₁˜C₁₂ alkyl, C₁˜C₁₂ alkoxy, or halogen, and n is an integer of 1, 2, or 3;
D₁, and D₂ are each independently C₁˜C₁₂ alkyl, 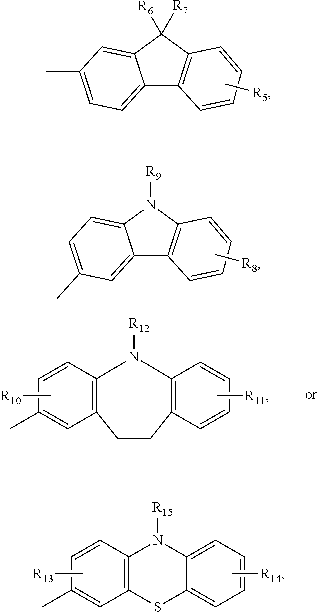
or D₁, D₂, and N bond together to form 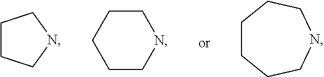
wherein, R₅, R₆, R₇, R₈, R₁₀, R₁₁, R₁₃, and R₁₄ are each independently H, C₁˜C₁₂ alkyl, C₁˜C₁₂ alkoxy, amino, or halogen, R₉, R₁₂, and R₁₅ are each independently H, or C₁˜C₁₂ alkyl;
B is 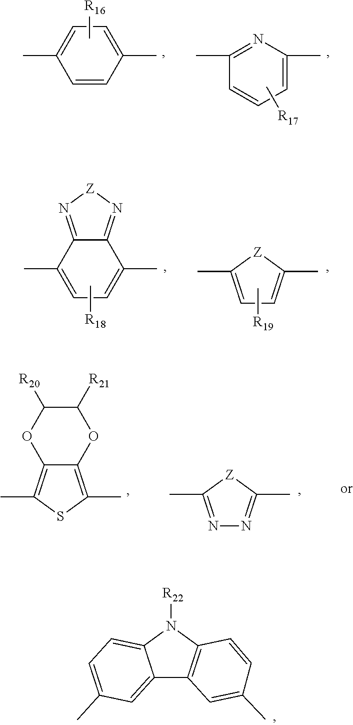
wherein R₁₆, R₁₇, and R₁₈ are each independently H, C₁˜C₁₂ alkyl, C₁˜C₁₂ alkoxy, or halogen, R₁₉, R₂₀, R₂₁, and R₂₂ are each independently H, or C₁˜C₁₂ alkyl, and Z is O, S, or Se; and (b) a second organic sensitized dye, wherein the difference of the maximum absorption wavelength between the first organic sensitized dye and the second organic sensitized dye is larger than 50 nm;
(B) a cathode; and
(C) an electrolyte layer, disposed between the photoanode and the cathode.

18. A method for manufacturing the dye-sensitized solar cell, comprising the following steps:
(1) providing an photoanode as claimed in claim 1;
(2) providing a second substrate;
(3) forming a metal layer on the second substrate;
(4) composing the photoanode and the second substrate, wherein the semiconductor layer faces to the metal layer, and a containing space is formed between the photoanode and the second substrate;
(5) filling the containing space with a electrolyte; and
(6) sealing the containing space.
